(19) United States
(12) Patent Application Publication
(10) Pub. No.: US 2016/0064436 A1
(43) Pub. Date: Mar. 3, 2016

(54) CIRCUIT-INTEGRATED PHOTOELECTRIC CONVERTER AND METHOD FOR MANUFACTURING THE SAME

(71) Applicant: SHARP KABUSHIKI KAISHA, Osaka (JP)

(72) Inventors: Masayo UCHIDA, Osaka-shi, Osaka (JP); Kazuhiro NATSUAKI, Osaka-shi, Osaka (JP); Takahiro TAKIMOTO, Osaka-shi, Osaka (JP); Nobuyoshi AWAYA, Osaka-shi, Osaka (JP); Kazuya ISHIHARA, Osaka-shi, Osaka (JP); Takashi NAKANO, Osaka-shi, Osaka (JP)

(73) Assignee: SHARP KABUSHIKI KAISHA, Osaka-shi, Osaka (JP)

(21) Appl. No.: 14/779,221

(22) PCT Filed: Feb. 27, 2014
(86) PCT No.: PCT/JP2014/054866

§ 371 Date: Sep. 22, 2015

(30) Foreign Application Priority Data
Apr. 23, 2013 (JP) 2013-090267

(51) Int. Cl. H01L 27/146

(52) U.S. Cl. CPC H01L 27/14621; H01L 27/14623; H01L 27/14636; H01L 27/14685

(57) ABSTRACT

A circuit-integrated photoelectric converter in which a dished portion is less likely to be formed in an insulating layer underlying a plasmonic filter portion and the plasmonic filter portion can be accurately and finely processed is provided and a method for manufacturing the same is provided. A metal layer (31) is disposed on an insulating layer (7) above a wiring layer (11, 12, 13). This metal layer (31) includes a plasmonic filter portion (32) and a shield metal portion (33) that blocks light. The plasmonic filter portion (32) having cyclic holes (32a) to guide light having a selected wavelength to a first photoelectric converting element (101).

### TECHNICAL FIELD

The present invention relates to a circuit-integrated photoelectric converter, such as a color sensor, and a method for manufacturing the same.

### BACKGROUND ART

The human eyes perceive changes in color to a lesser extent regardless of a change in color temperature of room illumination. This characteristic is generally called chromatic adaptation. When, for example, a person transfers from a room illuminated with bluish fluorescent light (having a high color temperature) to a room illuminated with yellowish incandescent light (having a low color temperature), he/she visually perceives a white wall in the room as a yellowish wall at first. Then, after a while, he/she visually perceives what he/she has visually perceived as the yellowish wall as a white wall.

Since the human visual system has this chromatic adaptation characteristic, a change of the color of room illumination causes a person to visually perceive a change of the color of a television image that remains having the same color. With the recent improvement of the image quality of a liquid crystal display television, the demand for the following function has been growing; the function with which an image is naturally viewed regardless of a change of the color temperature of room illumination by changing the color tone of the image in accordance with the type of the room illumination. Thus, liquid crystal display televisions integrated with a color sensor that detects the color temperature of the room have been increasing so that the color sensor detects the color temperature of the room and the color tone of the image is automatically controllable in conformity with the chromatic adaptation of the human eyes. For a liquid crystal display installed in a portable device such as a smart phone or a tablet personal computer (PC), a sensor that automatically detects the color temperature such as a color sensor has been becoming more important since the ambient illumination changes every moment under different viewing locations.

This color sensor separately senses spectral components of red (R), green (G), and blue (B) within the range from ambient light to visible light (herein after this color sensor is referred to as a RGB sensor).

This RGB sensor includes multiple photoelectric converting elements for sensing the ambient light. A device serving as each photoelectric converting element is generally constituted of a photodiode. This photodiode itself cannot identify the color; it can only detect the intensity of light (amount of light). Thus, in order to convert an image into electric signals, each photodiode is covered with a color filter for color identification and detects the amount of light of light components of red (R), green (G), and blue (B), which are the three primary colors of light, whereby color signals are acquired through the photodiodes.

An existing RGB sensor includes a color filter that transmits or reflects only light with a specific wavelength by blocking light with absorption with a material or by light interference in order to divide the ambient light into light of the three primary colors of red (R), green (G), and blue (B). The configuration of a red-green-blue (RGB) sensor illustrated in FIG. 6 is a typical configuration.

In FIG. 6, the reference numeral 100 denotes a semiconductor substrate made of a material such as silicon, the reference numeral 101 denotes a first photodiode disposed in correspondence with one of the RGB colors and detecting the amount of light of the RGB three primary colors, the reference numeral 102 denotes a circuit portion, the reference numerals 1, 2, 3, and 40 denote insulating layers made of a material such as SiO₂, the reference numerals 11, 12, and 13 denote wiring layers made of a material such as metal, the reference numeral 43 denotes a shield metal portion disposed in the same layer as the wiring layer 13, the reference numerals 51 and 52 denote an organic planarized layer made of acrylic resin, the reference numeral 53 denotes an organic color resist serving as a color filter that divides the ambient light into light components of the RGB three primary colors, and the reference numeral 20 denotes a via hole.

The existing RGB sensor, however, requires three types of photomask in order to form a color filter 53 constituted of an organic color resist that divides light into light components of the RGB three primary colors. This requirement of three types of photomask causes rises in time and costs in the manufacturing process.

In order to decrease the time and the cost, a configuration has been developed in which a metal thin film is subjected to nanoscale fine processing to serve as an optical wavelength selective filter in place of the above-described color filter 53. The optical wavelength selective filter having this configuration uses abnormal light transmission phenomenon due to surface plasmon resonance excited by incident light.

This wavelength selective filter using surface plasmon resonance is described in detail in PTL 1 (Japanese Unexamined Patent Application Publication No. 11-72607). Various methods are conceivable as a way of causing this abnormal transmission phenomenon. One example of such methods is to form a filter layer 500, as illustrated in FIG. 7, by forming a thin metal film 501 of approximately 50 to 200 nm and forming a pattern of hole arrays 502 finer than the transmission wavelength in this metal film 501. FIG. 8 illustrates a spectral wave form that transmits the filter layer 500 when light is incident on the filter layer 500. Here, the surface plasmon effect results from the resonance between the surface plasmon at the interface between a certain metal film and an insulator film or air and evanescent light caused by incident light. Thus, in order to efficiently produce the surface plasmon effect, a metal film or an insulator film preferably has a simple structure (uniform in material or property such as a refractive index or uniform in hole pitch or shape). Examples usable as the metal material include Au, Ag, and Al.

Particularly, Al is a material having various advantages such as:

(i) it causes a resonance phenomenon also in a short wavelength region due to its high plasma frequency,

(ii) it is a material normally used in a semiconductor process and thus dispenses with a device or material dedicated for itself even in terms of process integration,

(iii) it is a material reasonable in cost, and

(iv) it simplifies the manufacturing process and allows filters corresponding to different wavelengths to be collectively formed. Thus, Al is frequently used as a metal material.

Forming a metal film that causes the surface plasmon effect involves fine processing of holes on the 65 nm to 0.13 um level in accordance with the design rule.

According to NPL 1 (Focus 26, Vol. 3, Development of Color Filter Using Surface Plasmon Resonance, NIMS, TOYOTA CENTRAL R&D LABS., INC.), the pitch between holes 502 has to be approximately 260 nm and the diameter of each hole 502 has to be approximately 80 to 180 nm, as illustrated in FIG. 9, in order to form an Al film that transmits blue light having a wavelength of approximately 400 nm. Thus, as described above, in order to form a metal film filter that transmits light having wavelengths corresponding to the RGB colors, the pitch between holes 502 has to be approximately 260 nm for blue light transmission.

### CITATION LIST

### Patent Literature

PTL 1: Japanese Unexamined Patent Application Publication No. 11-72607

### Non Patent Literature

NPL 1: Focus 26, Vol. 3, Development of Color Filter Using Surface Plasmon Resonance, NIMS, TOYOTA CENTRAL R&D LABS., INC.

### SUMMARY OF INVENTION

### Technical Problem

FIG. 10 is a cross-sectional view of a circuit-integrated photoelectric converter prototyped during development of the invention. The circuit-integrated photoelectric converter illustrated in FIG. 10 is described for the purpose of convenience for describing the technical problem and is not a known technology (prior art).

In FIG. 10, the reference numeral 100 denotes a semiconductor substrate made of a material such as silicon, the reference numeral 101 is a first photodiode (although not illustrated, multiple first photodiodes corresponding to the RGB colors are disposed in a direction extending between the front and the back of FIG. 10) disposed in correspondence with one of the RGB colors and detecting the amount of light of the RGB three primary colors, the reference numeral 102 denotes a circuit portion, the reference numerals 1, 2, 3, and 50 denote insulating layers made of a material such as SiO₂, the reference numerals 11, 12, and 13 denote wiring layers made of a material such as metal, the reference numeral 42 denotes a plasmonic filter portion constituted of a metal film that divides the ambient light into the RGB three primary colors, the reference numeral 43 denotes a shield metal portion concurrently disposed in the same layer as the wiring layer 13 and covering a circuit portion 102, and the reference numeral 20 denotes a via hole.

In a plasmonic filter portion 42, the pitch between holes 42a has to be, for example, approximately 260 nm for the purpose of blue light transmission in the blue light transmission area. It is difficult to compatibly satisfy the photolithography exposure conditions of the hole arrays 42a of the plasmonic filter portion 42 constituted of a metal layer and the conditions of the fine metal wiring layers 11, 12, and 13 for achieving this purpose. The plasmonic filter portion 42, which is a metal film filter, is formed by including upper and lower separate layers different from the metal layers in the wiring layers 11, 12, and 13. With consideration of the possibility of replacement with an organic color resist used in an existing solid-state image sensing device or a color sensor, the plasmonic filter portion 42 is disposed above the wiring layer 13 and a shield metal portion 43, as illustrated in FIG. 10.

However, in the case where the plasmonic filter portion 42 is disposed above the wiring layer 13 and the shield metal portion 43, the following phenomenon occurs. As illustrated in FIG. 11, when an insulating layer 40 before being subjected to chemical mechanical polishing (CMP), which is illustrated in FIG. 10 and which is a layer before being processed into a planarized insulating layer 4, is deposited, a wide protruding portion 40a is formed in the insulating layer 40 over the shield metal portion 43 whereas a wide recessed portion 40b is formed in the insulating layer 40 over a first photodiode 101. Thus, a large difference in level is formed between the protruding portion 40a and the recessed portion 40b. The shield metal portion 43, which has caused this large difference in level, is provided for covering components including the circuit portion 102 other than the first photodiode 101 so as to prevent light causing aliases or noise from entering the first photodiode 101. Thus, the shield metal portion 43 is necessary for the circuit-integrated photoelectric converter to acquire accurate signals.

On the other hand, in the case where the insulating layer 40 having a large difference in level and the wide protruding portion 40a illustrated in FIG. 11 is subjected to CMP in a planarizing process to be processed into an insulating layer 4 illustrated in FIG. 12, a dished portion 4d is formed over the first photodiode 101 (for easy understanding, the dished portion 4d is exaggeratedly illustrated).

When the insulating layer 4 after CMP that has distortion at a portion over the first photodiode 101 due to the dished portion 4d is subjected to photolithography so that a pattern of fine holes 42a of the plasmonic filter portion 42 is formed on a metal film on the insulating layer 4, which is a substrate that has not been planarized, the fine pattern is transferred in a distorted manner, thereby failing to perform accurate fine processing required for the plasmonic filter portion 42.

In order to form the plasmonic filter portion 42, photolithography is performed on a metal film by nanoimprinting or by using a stepper or other devices to transfer the fine process pattern on the metal film. In order to form an accurate fine pattern, planarizing the insulator film 4 before being subjected to photolithography in the manner as illustrated in FIG. 13 is important.

Thus, an object of the invention is to provide a circuit-integrated photoelectric converter in which a dished portion is less likely to be formed in an insulating layer underlying a plasmonic filter portion and the plasmonic filter portion can be accurately and finely processed and another object of the invention is to provide a method for manufacturing the circuit-integrated photoelectric converter.

### Solution to Problem

In order to solve the above problem, a circuit-integrated photoelectric converter according to the invention includes at least one first photoelectric converting element and a circuit portion, disposed on a substrate, and a wiring layer, disposed on the substrate with an insulating layer interposed therebetween. The photoelectric converter includes a metal layer disposed on an insulating layer above the wiring layer, the metal layer including a plasmonic filter portion and a shield metal portion, the plasmonic filter portion having holes arranged cyclically or noncyclically to guide light having a selected wavelength to the first photoelectric converting element, the shield metal portion blocking light having a predetermined wavelength.

A method for manufacturing a circuit-integrated photoelectric converter according to the invention includes forming a first photoelectric converting element and a circuit portion on a substrate; stacking a plurality of wiring layers in order on the substrate with insulating layers interposed therebetween; forming a metal layer on an uppermost one of the plurality of wiring layers with an insulating layer interposed therebetween; and forming a plasmonic filter portion by cyclically or noncyclically forming holes on a part of the metal layer to guide light having a selected wavelength to the first photoelectric converting element and defining another part of the metal layer as a shield metal portion that blocks light having a predetermined wavelength.

### Advantageous Effects of Invention

According to the invention, a circuit-integrated photoelectric converter that includes a highly accurate plasmonic filter portion and that negligibly has a dished portion in an insulating layer under the plasmonic filter portion can be acquired.

### BRIEF DESCRIPTION OF DRAWINGS

FIG. 1 is a cross-sectional view illustrating a manufacturing process of a circuit-integrated photoelectric converter according to a first embodiment of the invention.

FIG. 2 is a cross-sectional view illustrating a manufacturing process of the circuit-integrated photoelectric converter according to the first embodiment.

FIG. 3 is a cross-sectional view illustrating a manufacturing process of the circuit-integrated photoelectric converter according to the first embodiment.

FIG. 4 is a cross-sectional view of the circuit-integrated photoelectric converter according to the first embodiment.

FIG. 5 is a cross-sectional view of a circuit-integrated photoelectric converter according to a second embodiment of the invention.

FIG. 6 is a cross-sectional view of a circuit-integrated photoelectric converter including an existing color filter.

FIG. 7 is a perspective view of a filter layer described in PTL 1, on which hole arrays are patterned.

FIG. 8 is a wave form graph of a wave form of spectral light that has transmitted through the filter layer described in PTL 1.

FIG. 9 illustrates an example of hole arrays of a blue-light transmissive filter.

FIG. 10 is a cross-sectional view of a circuit-integrated photoelectric converter prototyped during development of the invention.

FIG. 11 is a cross-sectional view illustrating the state where an insulating layer is formed during the process of manufacturing the circuit-integrated photoelectric converter.

FIG. 12 is a cross-sectional view illustrating the state where an insulating layer of the circuit-integrated photoelectric converter is polished by CMP.

FIG. 13 is a cross-sectional view illustrating the state where the insulator film is ideally planarized.

### DESCRIPTION OF EMBODIMENTS

Hereinbelow, the invention is described in detail using embodiments illustrated in the drawings.

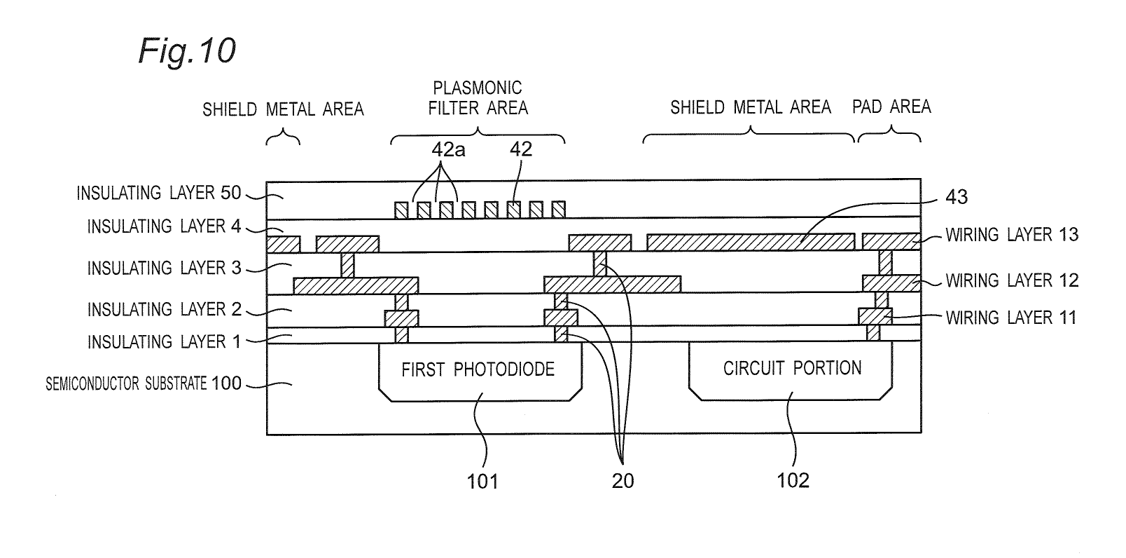

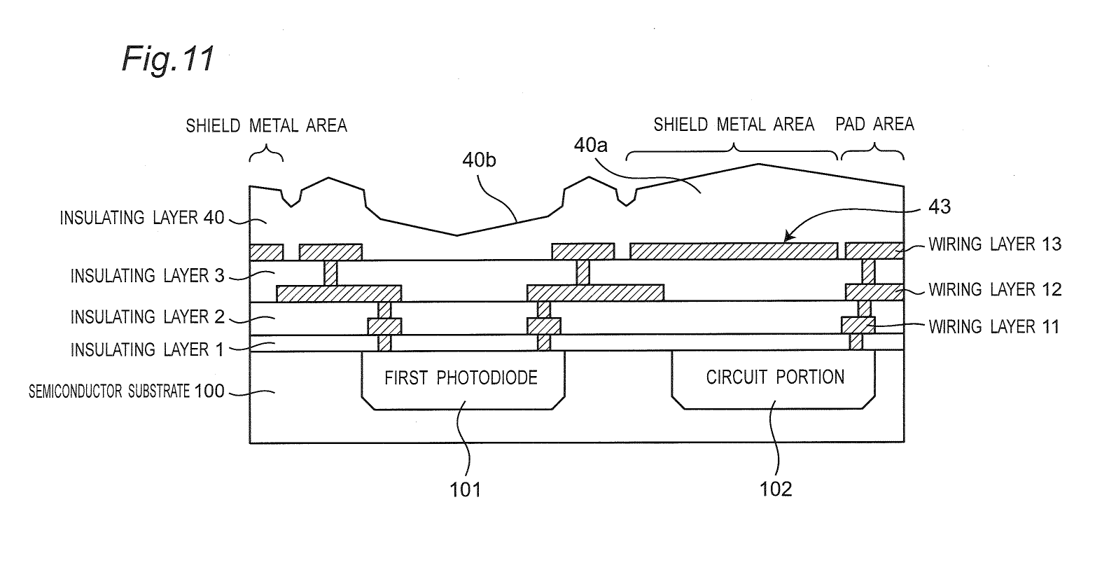

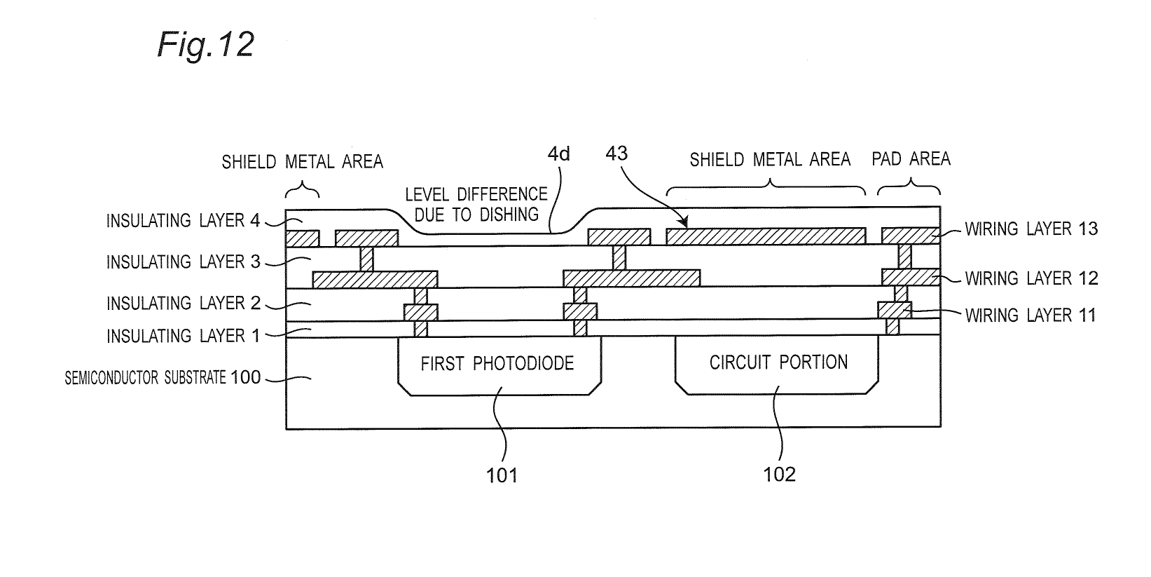

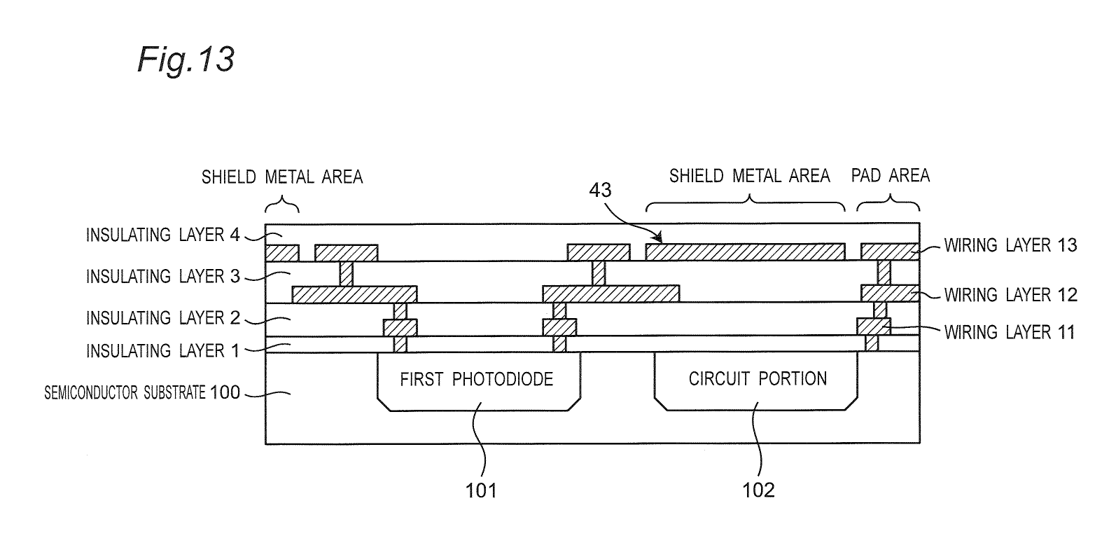

Components the same as or similar to the components illustrated in FIG. 10 are denoted by the same reference numerals as those of the components illustrated in FIG. 10 and the configurations and the effects of these components are not described in detail. Only the components different from the components illustrated in FIG. 10 are described below.

### First Embodiment

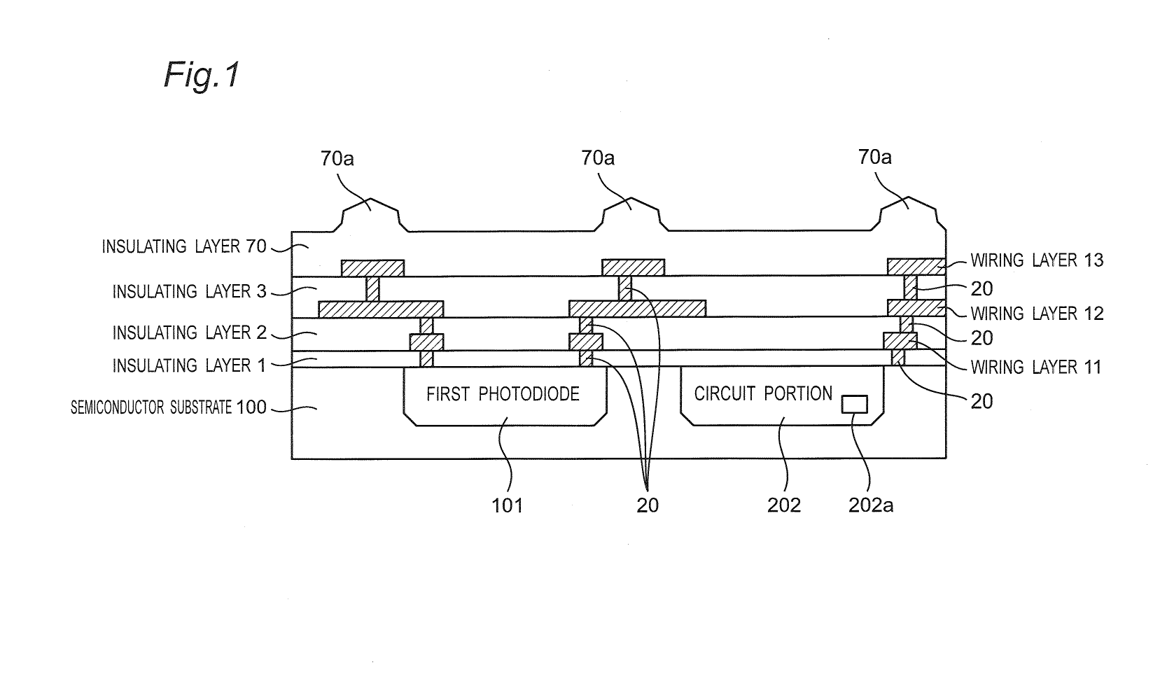

Referring to FIG. 1 to FIG. 4, a method for manufacturing a circuit-integrated photoelectric converter according to a first embodiment of the invention is described.

As illustrated in FIG. 1, a first photodiode 101, which is an example of a first photoelectric converting element that converts incident light into electric signals, and a circuit portion 202, which processes the electric signals, are formed at predetermined positions on a semiconductor substrate 100 made of a material such as silicon. At this time, an area for disposing a pad, which is a terminal that outputs electric signals, besides the circuit portion 202 is concurrently reserved. The circuit portion 202 includes an electrostatic protection element 202a.

Wiring layers 11, 12, and 13 made of a material such as metal are stacked on a portion above the semiconductor substrate 100 and around the first photodiode 101 and on a portion above the circuit portion 202 with insulating layers 1, 2, and 3 made of a material such as SiO₂ interposed therebetween to form a multilayer wiring. Here, a shield metal portion 43 such as the one illustrated in FIG. 10 and disposed on the same layer as the wiring layer 13 is not formed. The wiring layer 13 does not have a large flat portion serving as a shield metal portion and is used only as a wire.

Subsequently, as illustrated in FIG. 1, an insulating layer 70 made of a material such as SiO₂ is deposited by a method such as chemical vapor deposition (CVD) at a portion further above the insulating layer 3 and the wiring layer 13. At this time, narrow projecting protrusions 70a are formed above the wiring layer 13 so as to correspond to the wiring layer 13. The configuration in FIG. 1 does not include a wide shield metal portion 43, as illustrated in FIG. 10, disposed on the same layer as the wiring layer 13. Thus, unlike the configuration in FIG. 10, only narrow projecting protrusions 70a develop on the insulating layer 70. Unlike the case of a wide flat protruding portion 40a illustrated in FIG. 10, these narrow projecting protrusions 70a locally receive a relatively large polishing pressure during the CMP process. Thus, these protrusions 70a are easily polished and easily planarized and the polishing time in CMP can be minimized. As described above, the insulating layer 70 has a shape that minimizes an occurrence of a dished portion and that is easily planarized.

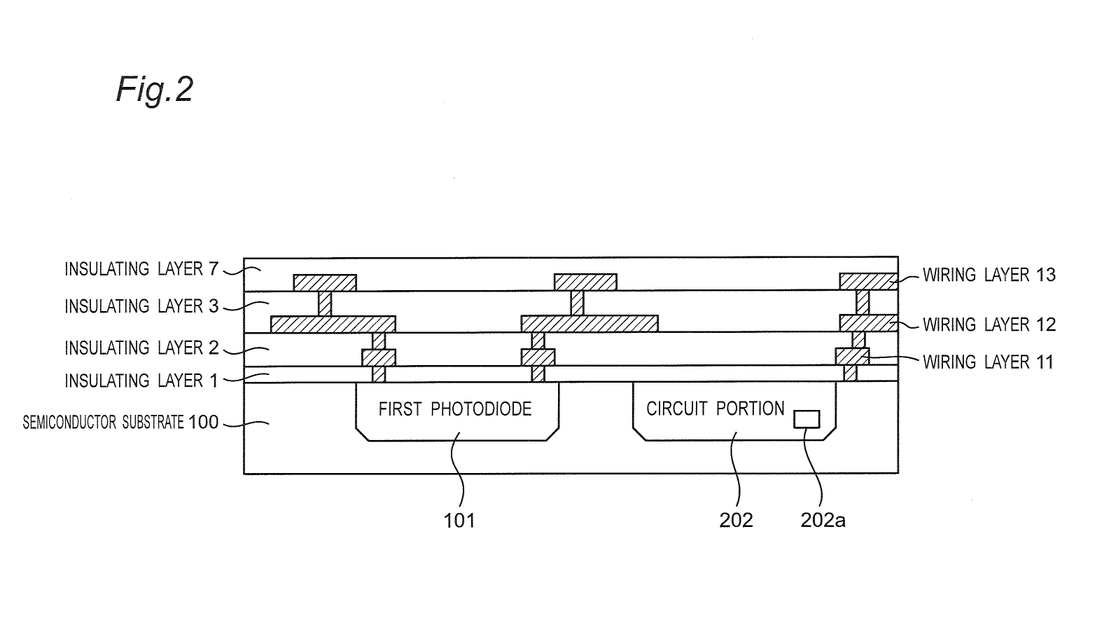

The insulating layer 70 is processed by CMP until becoming completely planarized to form a planarized insulating layer 7 having a negligible dished portion, as illustrated in FIG. 2. This surface planarization of the insulating layer 7 becomes extremely important in a subsequent step of forming a metal plasmonic filter portion having fine holes using fine pattern photolithography or other methods.

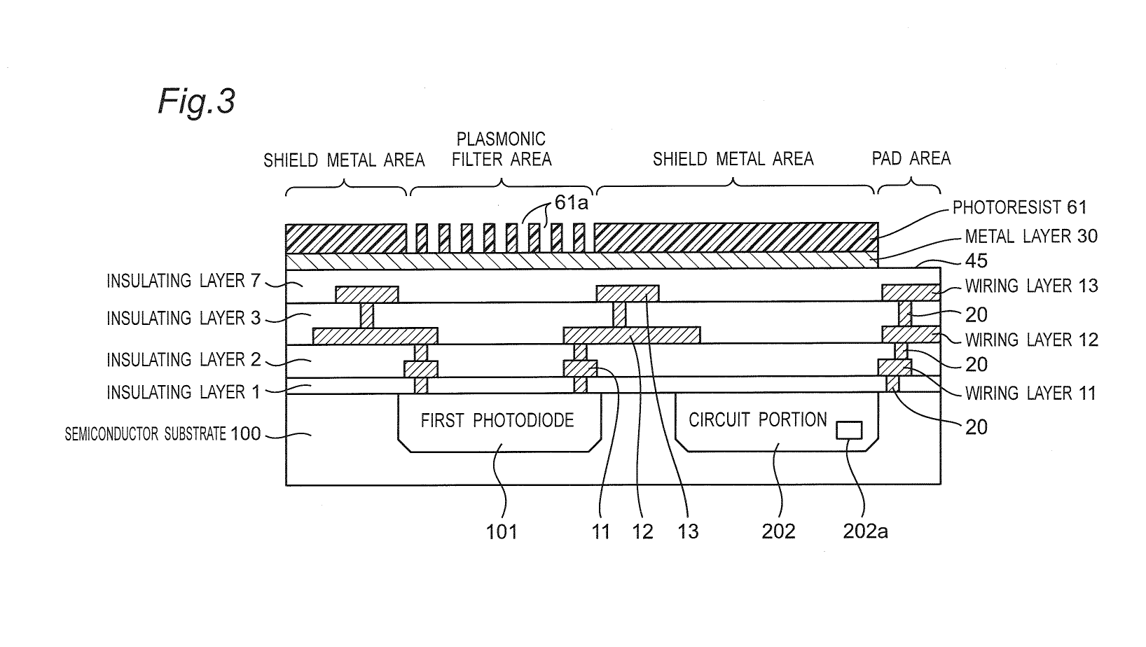

Subsequently, as illustrated in FIG. 3, a metal layer 30 serving as a filter material is formed by sputtering on the planarized insulating layer 7 so as to have a thickness of, for example, 150 nm. The most preferable metal for the filter material is Al in terms of its material uniformity, but the filter material may be AlCu or AlSi typically used for semiconductor manufacturing. In addition, the thickness of the metal layer 30 is not limited to 150 nm and may be approximately 50 to 200 nm.

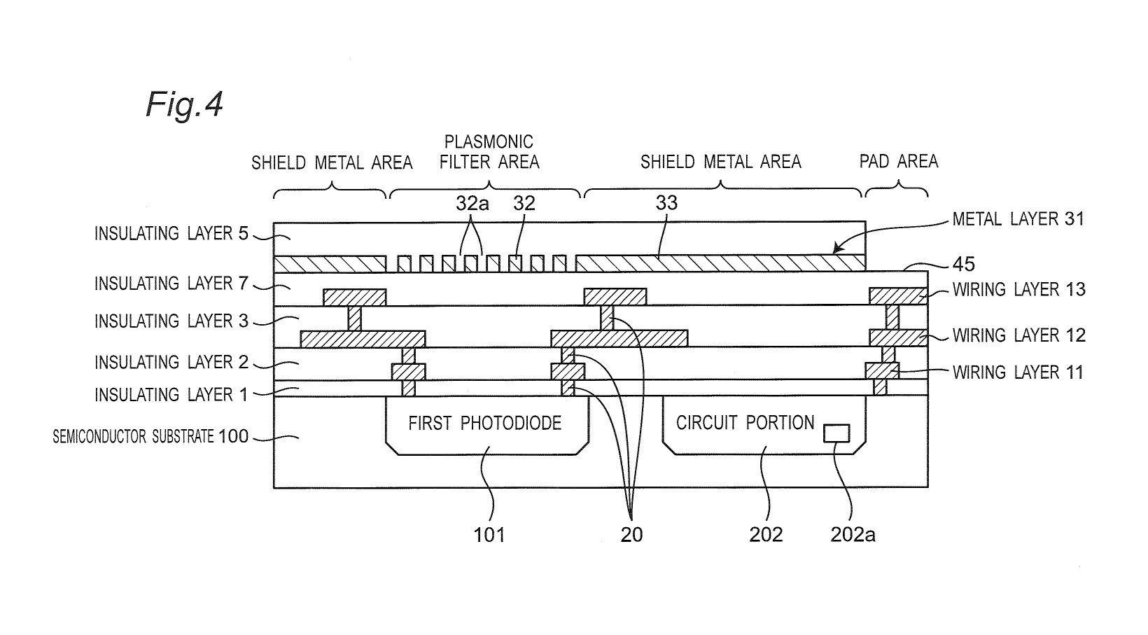

In order to define, in a subsequent step, a shield metal portion 33 (see FIG. 4) for blocking light on the same metal layer 30, the metal layer 30 has to have a layer thickness that can block light having a predetermined wavelength, such as a wavelength of 300 nm to 1200 nm. This is because the wavelength of light that transmits silicon well falls within the range of 300 nm to 1200 nm. Thus, when the shield metal portion 33 has a layer thickness that can block light having a wavelength of 300 nm to 1200 nm that transmits silicon well, light causing noise or aliases can be prevented from entering the first photodiode 101 or the circuit portion 202 even when components including the insulating layers 1, 2, 3, and 7, the first photodiode 101, the circuit portion 202, and the substrate 100 are made of silicon.

As illustrated in FIG. 3, a pad area 45 from which an electrode is drawn is exposed without being covered with the metal layer 30.

Subsequently, as illustrated in FIG. 3, a photoresist 61 is applied to the surface of the metal layer 30 and hole patterns 61a are formed on the photoresist 61 by photolithography. These hole patterns 61a correspond to a plasmonic filter portion 32 functioning as a wavelength selective filter illustrated in FIG. 4 and are disposed above a light-receiving hole of the first photodiode 101. Then, the metal layer 30 is etched using the photoresist 61 as a mask to form a metal layer 31 including the plasmonic filter portion 32 and a shield metal portion 33 illustrated in FIG. 4. Thereafter, the photoresist 61 is removed.

The plasmonic filter portion 32 and the shield metal portion 33 are included in the same metal layer 31 and a shield metal portion having an area as large as the area of the shield metal portion 33 is not provided below the metal layer 31. Thus, unlike in the above-described case, a dished portion is less likely to be formed in the insulating layer 7 under the metal layer 31 after performing CMP. Thus, holes 32a that require nanoscale fine processing on the plasmonic filter portion 32 can be accurately and speedily processed into a uniform shape by a method such as photolithography.

As illustrated in FIG. 4, the plasmonic filter portion 32 and the shield metal portion 33 in the metal layer 31 are continuous with each other so that the yield of deposit at the etching is reduced. However, the plasmonic filter portion and the shield metal portion do not have to be continuous and may be separated from each other, although not illustrated.

The shield metal portion 33 covers the circuit portion 202, the area between the first photodiode 101 and the circuit portion 202, and the areas at the outer side of the first photodiode 101. This configuration thus prevents stray light from entering the first photodiode 101 or the circuit portion 202 and an occurrence of aliases, thereby preventing malfunction and improving the durability.

The metal layer 31 or the shield metal portion 33 is grounded using wires not illustrated and has a ground potential. Thus, the metal layer 31 or the shield metal portion 33 is effective in not only blocking light but also blocking electric noise. For example, when electric noise arises at the metal layer 31 or the shield metal portion 33, this electric noise can escape to the ground potential. Thus, the electric noise does not adversely affect the circuit portion 202 or the electrostatic protection element 202a disposed below the metal layer 31 or the shield metal portion 33. Specifically, the shield metal portion 33 functions as a shield that blocks entrance of light and that protects components including the circuit portion 202 against electric noise.

The shield metal portion 33 covers half the area of the surface of the substrate 100 or more. Thus, the area of the original metal layer 30 that is to be etched can be reduced, thereby minimizing the production of deposit or other matter when the original metal layer 30 is etched with a device such as a metal etcher.

The hole pattern of the holes 32a of the plasmonic filter portion 32 is two-dimensionally cyclic. In this first embodiment, the holes 32a are through holes but may be recesses instead of through holes. The shape of the holes 32a is not limited to a circle and may be other shapes such as a rectangle or a triangle.

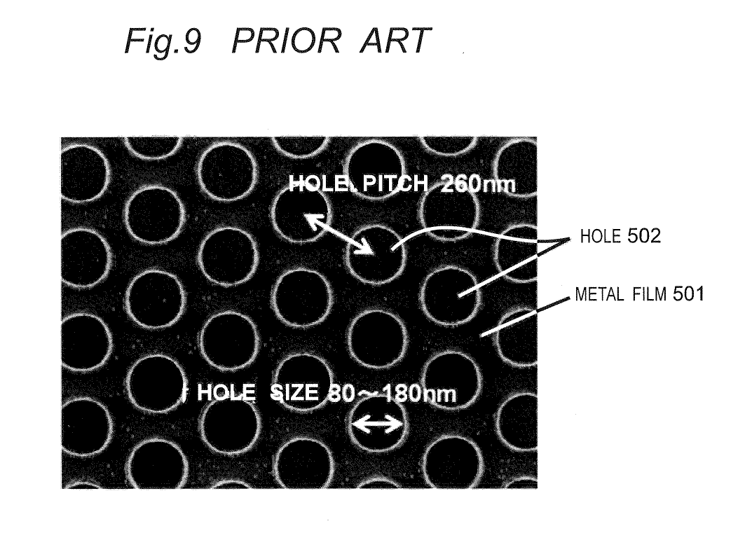

When the holes 32a arranged two-dimensionally cyclically are formed on the plasmonic filter portion 32 of the metal layer 31, a surface plasmon dispersion relation is established at the holes 32a arranged two-dimensionally cyclically and the surface plasmons can be excited by light, whereby the plasmonic filter portion 32 of the metal layer 31 can be caused to function as a wavelength selective filter (see NPL 1). At this time, electrons oscillate similarly at adjacent holes 32a, and the entire surface exhibits a behavior of collective excitation. Thus, an arrangement in which adjacent holes 32a are spaced at the same hole pitch is optimum. A staggered arrangement, such as the one illustrated in FIG. 9, in which six holes surround one hole has a uniform hole pitch and thus a high color resolving power can be acquired (see NPL 1).

Although not illustrated, the holes 32a cyclically formed on the plasmonic filter portion 32 of the metal layer 31 form hole arrays having different cycles for R, G, and B, in order to transmit light of R (having a wavelength of 660 nm), G (having a wavelength of 540 nm), and B (having a wavelength of 440 nm). These hole arrays for R, G, and B are arranged in a direction, for example, extending between the front and the rear of FIG. 4.

In the case where Al, AlCu, or AlSi is used as a material of the metal layer 31 and the hole arrays 32a of the metal layer 31 are coated with an insulating layer 5 made of a material such as SiO₂, the conditions under which surface plasmons are excited by vertical light incidence include the following formula: normalized frequency a/λ=0.65 (Formula 1) (see NPL 1). Here, a denotes the cycle of the hole arrays 32a. From Formula 1, the cycles a of the respective hole arrays that transmit light of R, G, and B are calculated as 420 nm for R, 340 nm for G, and 260 nm for B. From Formula 1, changing the cycle of the hole arrays 32a, that is, the arrangement cycle of the holes 32a enables selection of which light is to be transmitted. Thus, forming different cycle arrangement patterns on a single photomask allows wavelength selective filters for R, G, and G light to be concurrently formed in a single operation of photolithography.

As illustrated in FIG. 4, after the plasmonic filter portion 32 is formed by forming hole arrays 32a of the metal layer 31, an insulating layer 5 functioning as a protective film made of SiO₂ is formed over the metal layer 31 and the insulating layer 7. At this time, the holes (through holes or recesses) 32a of the plasmonic filter portion 32 of the metal layer 31 formed in the previous step need to be filled with the insulating layer 5, that is, SiO₂. Thus, the insulating layer 5 made of SiO₂ is formed by high-density plasma CVD.

Finally, a portion of the insulating layer 5 made of SiO₂ covering a pad area 45 exposed from the metal layer 31 is removed to expose the pad area 45. Then, in this pad area 45, a pad portion formed of a metal film thicker than the metal layer 31 is formed, although the pad portion is not illustrated.

The reason why the pad portion is exposed from the metal layer 31 in this manner is as follows. The metal layer 31 including the plasmonic filter portion 32 using the plasmon resonance is formed thinner than the film thickness of the metal film serving as the pad portion. Thus, if a part of the metal layer 30 is used as a metal film serving as the pad portion, malfunction may occur during testing or wire bonding. In the first embodiment, the pad portion, which is not illustrated, formed in the pad area 45 is exposed from the metal layer 30. Thus, appropriately determining the thickness of a metal film, not illustrated, of the pad portion can prevent an occurrence of malfunction.

### Second Embodiment

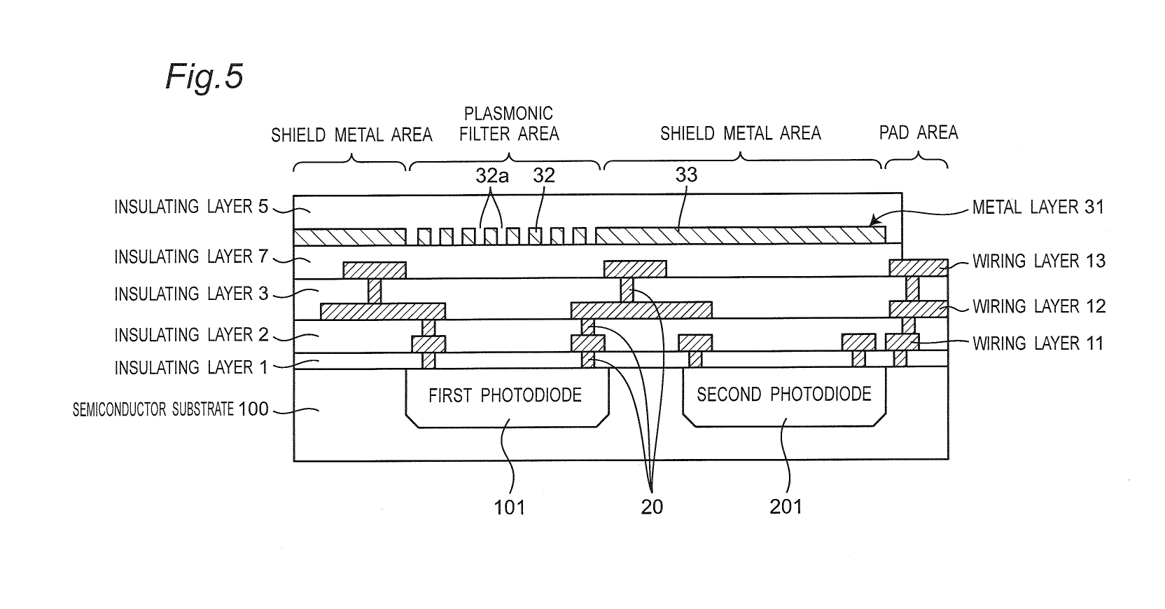

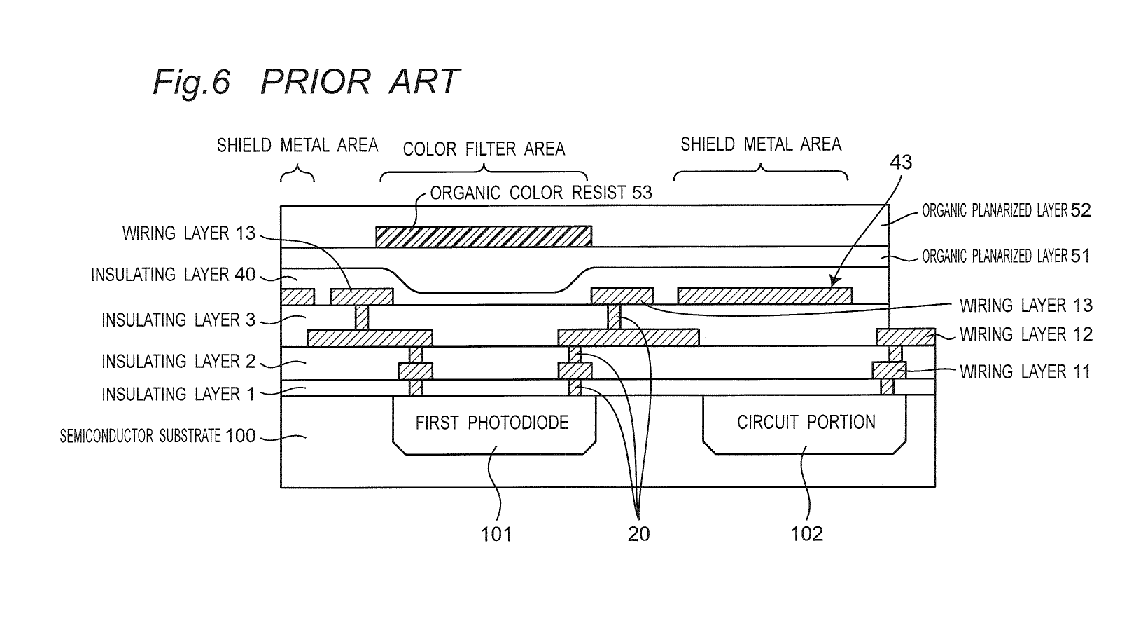

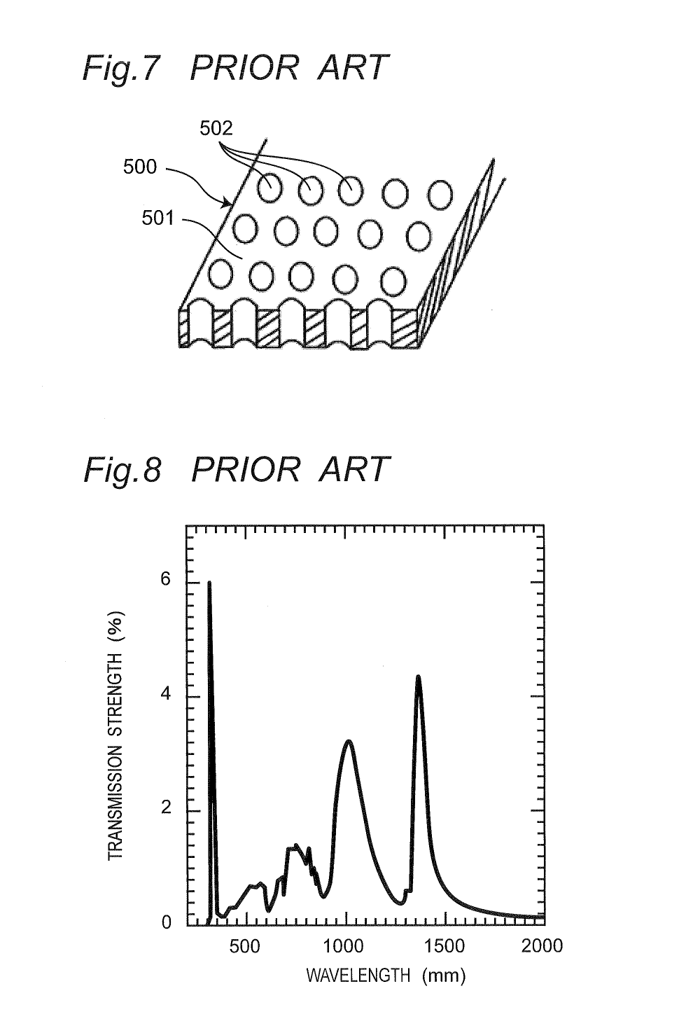

FIG. 5 is a cross-sectional view of a circuit-integrated photoelectric converter according to a second embodiment of the invention. In FIG. 5, components that are the same as the components of the circuit-integrated photoelectric converter according to the first embodiment illustrated in FIG. 4 are denoted by the same reference numerals as those of the components illustrated in FIG. 4. The operations and effects of these components are not described in detail. Only the components different from the components illustrated in FIG. 4 are described below.

As illustrated in FIG. 5, beside the first photodiode 101 serving as a first photoelectric converting element, a second photodiode 201 serving as a second photoelectric converting element for reference is formed on a substrate 100 made of silicon. The second photodiode 201 has exactly the same configuration and properties as the first photodiode 101. Although not illustrated, a circuit portion, as in the case of the configuration illustrated in FIG. 1, is also provided on the substrate 100.

The metal layer 31 includes a plasmonic filter portion 32 and a shield metal portion 33. The shield metal portion 33 covers the circuit portion, the second photodiode 201, and an area between the first photodiode 101 and the second photodiode 201.

The circuit-integrated photoelectric converter according to the second embodiment includes a second photodiode 201 for reference covered with the shield metal portion 33. Thus, the difference between an output from the first photodiode 101 and an output from the second photodiode 201 for reference, which is covered with the shield metal portion 33 and does not receive light, is calculated by, for example, a differential circuit, not illustrated, whereby dark output correction can be performed.

In this second embodiment, the shield metal portion 33 covers the circuit portion, the second photodiode 201, and the area between the first photodiode 101 and the second photodiode 201. This configuration can thus prevent stray light or the like from entering the first and second photodiodes 101 and 201 and thus prevent an occurrence of aliases.

The shield metal portion 33 of the metal layer 31 also covers the second photodiode 201 besides the circuit portion. Thus, a portion that shields the second photodiode 201 (shield metal portion) and a portion that shields the circuit portion can be concurrently formed at low costs, whereby the circuit portion and the second photodiode 201 can be shielded at low costs.

In the first and second embodiments, photodiodes are used as photoelectric converting elements. However, a phototransistor or a solid-state image sensing device may be used, instead.

The invention and the embodiments are summarized as follows.

A circuit-integrated photoelectric converter according to the invention is a circuit-integrated photoelectric converter that includes at least one first photoelectric converting element 101 and a circuit portion 202, disposed on a substrate 100, and a wiring layer 11, 12, or 13, disposed on the substrate 100 with an insulating layer 1, 2, or 3 interposed therebetween. The photoelectric converter includes a metal layer 31 on an insulating layer 7 above the wiring layer 11, 12, or 13. The metal layer 31 includes a plasmonic filter portion 32 and a shield metal portion 33. The plasmonic filter portion 32 has holes 32a arranged cyclically or noncyclically to guide light having a selected wavelength to the first photoelectric converting element 101. The shield metal portion 33 blocks light having a predetermined wavelength.

Here, the light having a predetermined wavelength is light having a wavelength that causes aliases or noise.

According to the circuit-integrated photoelectric converter having the above-described configuration, the metal layer 31 includes the plasmonic filter portion 32 and the shield metal portion 33 and no shield metal portion having an area as large as the area of the shield metal portion 33 is provided below the insulating layer 7 underlying the metal layer 31. Thus, a wide protruding portion is less likely to develop on the insulating layer 70 before being processed, which is to underlie the metal layer 31, whereby only small irregularities are formed in the insulating layer 70. Thus, a dished portion is less likely to be formed under the plasmonic filter portion 32 on the insulating layer 7 obtained after performing chemical mechanical polishing (CMP) on the insulating layer 70 for planarization.

The insulating layer 7 underlying the metal layer 31 can thus be highly accurately planarized, whereby the holes 32a that require nanoscale fine processing of the plasmonic filter portion 32 can be highly accurately processed and the CMP processing time can be reduced. In addition, the nanoscale holes 32a in the plasmonic filter portion 32 can be readily formed into a uniform shape by a method such as photolithography.

The plasmonic filter portion 32 and the shield metal portion 33 are preferably continuous with each other so that the yield of deposit can be reduced. Nevertheless, the plasmonic filter portion and the shield metal portion may be separated from each other.

In one embodiment, the shield metal portion 33 covers at least the circuit portion 202.

In the above-described embodiment, the shield metal portion 33 covers the circuit portion 202 and blocks light having a predetermined wavelength. This configuration can thus prevent the circuit portion 202 or the first photoelectric converting element 101 from malfunctioning attributable to light and improve the durability.

In one embodiment, the shield metal portion 33 has a ground potential.

In the above-described embodiment, the shield metal portion 33 that covers the circuit portion 202 has a ground potential. Thus, the shield metal portion 33 is effective in not only blocking light but also blocking electric noise. For example, when electric noise arises at the metal layer 31 or the shield metal portion 33, this electric noise can escape to the ground potential. Thus, the electric noise does not adversely affect the circuit portion 202 disposed below the shield metal portion 33. Specifically, the shield metal portion 33 can prevent entrance of light and the electric noise and thus functions as a shield against light and electricity.

In one embodiment, the shield metal portion 33 covers the area between the first photoelectric converting element 101 and the circuit portion 202.

In the above-described embodiment, the shield metal portion 33 covers the area between the first photoelectric converting element 101 and the circuit portion 202. This configuration can thus prevent stray light from entering the first photoelectric converting element 101 and prevent an occurrence of aliases.

In one embodiment, the shield metal portion 33 covers half the area of a surface of the substrate 100 or more.

In the above-described embodiment, the shield metal portion 33 covers half the area of a surface of the substrate 100 or more. This configuration can thus reduce the area of the original metal layer 30, which is a base of the metal layer 31, that is to be etched and can reduce the yield of deposit or other matter resulting from etching of the original metal layer 30 using a device such as a metal etcher.

When an excessively large area of the original metal layer 30 is etched, a high yield of deposit is produced from the etching. In this embodiment, however, half the area of the surface of the substrate 100 or more is covered by the shield metal portion 31, whereby the yield of deposit can be reduced.

One embodiment includes a second photoelectric converting element 201 for reference and the shield metal portion 33 covers the second photoelectric converting element 201.

In the above-described embodiment, the difference between an output from the first photodiode 101 and an output from the second photodiode 201 for reference, which is covered with the shield metal portion 33 and does not receive light, is calculated by, for example, a differential circuit, whereby dark output correction can be performed.

In addition, in this embodiment, the shield metal portion 33 of the metal layer 31 also covers the second photodiode 201 besides the circuit portion 202. Thus, a portion that shields the second photodiode 201 (shield metal portion) and a portion that shields the circuit portion 202 can be concurrently formed at low costs, whereby the circuit portion 202 and the second photodiode 201 can be shielded at low costs.

In one embodiment, the shield metal portion 33 covers the area between the first photoelectric converting element 101 and the second photoelectric converting element 201.

In the above-described embodiment, the shield metal portion 33 covers the area between the first photoelectric converting element 101 and the second photoelectric converting element 201. This configuration can thus prevent stray light from entering the first and second photoelectric converting elements 101 and 201 and prevent an occurrence of aliases.

In one embodiment, the circuit portion 202 includes an electrostatic protection element 202a.

In the above-described embodiment, the shield metal portion 33 covers the electrostatic protection element 202a of the circuit portion 202 and thus the electrostatic protection element 202a is protected from electric noise. This configuration can thus prevent the electrostatic protection element 202a from malfunctioning.

One embodiment includes a pad portion and the pad portion is exposed from the metal layer 31.

The metal layer 31 including the plasmonic filter portion 32 using the plasmon resonance is formed thinner than the film thickness of the metal film serving as the pad portion. Thus, if the pad portion is formed on the metal layer 31, malfunction may occur during testing or wire bonding.

In this embodiment, the pad portion is not formed on the metal layer 31 and is exposed from the metal layer 31. Thus, appropriately determining the thickness of the pad portion can prevent an occurrence of malfunction.

In one embodiment, a plurality of the wiring layers 11, 12, and 13 are disposed on the substrate 100 so as to form multilayer wiring and the metal layer 31 is disposed on an uppermost one 13 of the plurality of wiring layers 11, 12, and 13 with the insulating layer 7 interposed therebetween.

According to the above-described embodiment, the metal layer 31 is disposed on an uppermost one 13 of the plurality of wiring layers 11, 12, and 13 with the insulating layer 7 interposed therebetween. Thus, the metal layer 31 including the plasmonic filter portion 32 and the shield metal portion 33 can be formed at the same level as an organic color resist used for a device such as an existing solid-state image sensing device or a color sensor, whereby an existing organic color resist and the metal layer 31 can be easily replaced with each other.

In one embodiment, the metal layer 31 is made of Al or AlCu.

Since Al has a high plasma frequency, Al can cause a plasmon resonance phenomenon also in a short wavelength region. Al is thus a material suitable for forming a plasmonic filter portion that transmits light having a 440-nm wavelength, which is a wavelength for blue (B), in a RGB color sensor.

In the above-described embodiment, the metal layer 31 is made of Al or AlCu. Thus, a plasmonic filter portion that transmits light having a wavelength for B can be reliably formed.

In one embodiment, the metal layer 31 has a thickness that prevents at least light having a predetermined wavelength from transmitting the metal layer 31.

Here, the light having a predetermined wavelength is light having a wavelength that causes aliases or noise.

In the above-described embodiment, the metal layer 31 has a thickness that prevents at least light having a predetermined wavelength from transmitting the metal layer 31. Thus, aliases or noise can be reliably prevented from occurring.

In one embodiment, the metal layer 31 has a thickness that prevents light having a wavelength within the range of 300 nm to 1200 nm from transmitting the metal layer 31.

The wavelength of light that transmits silicon well falls within the range of 300 nm to 1200 nm.

In the above-described embodiment, the metal layer 31 has a thickness that prevents light having a wavelength within the range of 300 nm to 1200 nm from transmitting the metal layer 31. Thus, the metal layer 31 can block light having a wavelength within the range of 300 nm to 1200 nm, which transmits silicon.

Thus, even in the case where components including the insulating layers 1, 2, 3, 7, and 5, the first photoelectric converting element 101, the circuit portion 202, and the substrate 100 are made of silicon, light causing noise or aliases can be prevented from entering the first photoelectric converting element 101 or the circuit portion 202.

In one embodiment, the plasmonic filter portion 32 of the metal layer 31 selectively transmits light of the three primary colors.

In the above-described embodiment, the plasmonic filter portion 32 selectively transmits light of the three primary colors. Thus, the plasmonic filter portion 32 can reliably detect light of each of the three primary colors.

A method for manufacturing a circuit-integrated photoelectric converter according to the invention includes forming a first photoelectric converting element 101 and a circuit portion 202 on a substrate 100; stacking a plurality of wiring layers 11, 12, and 13 in order on the substrate 100 with insulating layers 1, 2, and 3 interposed therebetween; forming a metal layer 31 on an uppermost one 13 of the plurality of wiring layers 11, 12, and 13 with an insulating layer 7 interposed therebetween; and forming a plasmonic filter portion 32 by cyclically or noncyclically forming holes 32a on a part of the metal layer 31 to guide light having a selected wavelength to the first photoelectric converting element 101 and defining another part of the metal layer 31 as a shield metal portion 33 that blocks light having a predetermined wavelength.

The method for manufacturing a circuit-integrated photoelectric converter according to the invention enables reliable and reasonable production of the above-described circuit-integrated photoelectric converter that is advantageous in that a plasmonic filter portion 32 can be highly accurately and speedily formed.

### REFERENCE SIGNS LIST

1, 2, 3, 4, 5, 7, 40, 70 insulating layer

11, 12, 13 wiring layer

30, 31 metal layer

32, 42 plasmonic filter portion

32a, 501 hole

33, 43 shield metal portion

45 pad area

100 substrate

101 first photodiode

201 second photodiode

102, 202 circuit portion

202a electrostatic protection element

1.-5. (canceled)

6. A circuit-integrated photoelectric converter that includes at least one first photoelectric converting element and a circuit portion, disposed on a substrate, and a wiring layer, disposed on the substrate with an insulating layer interposed therebetween, the photoelectric converter comprising:
a metal layer disposed on an insulating layer above the wiring layer, the metal layer including a plasmonic filter portion and a shield metal portion, the plasmonic filter portion having holes arranged cyclically or noncyclically to guide light having a selected wavelength to the first photoelectric converting element, the shield metal portion blocking light having a predetermined wavelength,
wherein the plasmonic filter portion and the shield metal portion are continuous with each other and the shield metal portion is grounded through a wire and has a ground potential.

7. A circuit-integrated photoelectric converter that includes at least one first photoelectric converting element and a circuit portion, disposed on a substrate, and a wiring layer, disposed on the substrate with an insulating layer interposed therebetween, the photoelectric converter comprising:
a metal layer disposed on an insulating layer above the wiring layer, the metal layer including a plasmonic filter portion and a shield metal portion, the plasmonic filter portion having holes arranged cyclically or noncyclically to guide light having a selected wavelength to the first photoelectric converting element, the shield metal portion blocking light having a predetermined wavelength,
wherein the plasmonic filter portion and the shield metal portion are continuous with each other.

8. The circuit-integrated photoelectric converter according to claim 6, further comprising:
a second photoelectric converting element (201) for reference,
wherein the shield metal portion (33) covers the second photoelectric converting element (201).

9. The circuit-integrated photoelectric converter according to claim 6
wherein a plurality of the wiring layers (11, 12, 13) are disposed on the substrate (100) so as to form multilayer wiring, and
wherein the metal layer (31) is disposed on an uppermost one (13) of the plurality of wiring layers (11, 12, 13) with the insulating layer (7) interposed therebetween.

10. A method for manufacturing a circuit-integrated photoelectric converter, comprising:
forming a first photoelectric converting element (101) and a circuit portion (202) on a substrate (100);
stacking a plurality of wiring layers (11, 12, 13) in order on the substrate (100) with insulating layers (1, 2, 3) interposed therebetween;
forming a metal layer (31) on an uppermost one (13) of the plurality of wiring layers (11, 12, 13) with an insulating layer (7) interposed therebetween; and
forming a plasmonic filter portion (32) by cyclically or noncyclically forming holes (32a) on a part of the metal layer (31) to guide light having a selected wavelength to the first photoelectric converting element (101) and, defining another part of the metal layer (31) as a shield metal portion (33) that blocks light having a predetermined wavelength, continuously forming the plasmonic filter portion (32) and the shield metal portion (33), and grounding the shield metal portion (33) through a wire so that the shield metal portion (33) has a ground potential.

11. A method for manufacturing a circuit-integrated photoelectric converter, comprising:
forming a first photoelectric converting element (101) and a circuit portion (202) on a substrate (100);
stacking a plurality of wiring layers (11, 12, 13) in order on the substrate (100) with insulating layers (1, 2, 3) interposed therebetween;
forming a metal layer (31) on an uppermost one (13) of the plurality of wiring layers (11, 12, 13) with an insulating layer (7) interposed therebetween; and
forming a plasmonic filter portion (32) by cyclically or noncyclically forming holes (32a) on a part of the metal layer (31) to guide light having a selected wavelength to the first photoelectric converting element (101), and defining another part of the metal layer (31) as a shield metal portion (33) that is continuous with the plasmonic filter portion (32) and that blocks light having a predetermined wavelength.

12. The circuit-integrated photoelectric converter according to claim 7, further comprising:
a second photoelectric converting element (201) for reference,
wherein the shield metal portion (33) covers the second photoelectric converting element (201).

13. The circuit-integrated photoelectric converter according to claim 7
wherein a plurality of the wiring layers (11, 12, 13) are disposed on the substrate (100) so as to form multilayer wiring, and
wherein the metal layer (31) is disposed on an uppermost one (13) of the plurality of wiring layers (11, 12, 13) with the insulating layer (7) interposed therebetween.

14. The circuit-integrated photoelectric converter according to claim 8
wherein a plurality of the wiring layers (11, 12, 13) are disposed on the substrate (100) so as to form multilayer wiring, and
wherein the metal layer (31) is disposed on an uppermost one (13) of the plurality of wiring layers (11, 12, 13) with the insulating layer (7) interposed therebetween.
